(19) United States
(12) Patent Application Publication
(10) Pub. No.: US 2009/0065890 A1
(43) Pub. Date: Mar. 12, 2009

(54) SEMICONDUCTOR DEVICE AND METHOD FOR FABRICATING THE SAME

(76) Inventor: Yong-Keon Choi, Gangnam-gu (KR)

Correspondence Address: SHERR & VAUGHN, PLLC, 620 HERNDON PARKWAY, SUITE 200, HERNDON, VA, 20170, US

(21) Appl. No.: 12/197,266

(22) Filed: Aug. 24, 2008

(30) Foreign Application Priority Data
Sep. 7, 2007 (KR) 10-2007-0090912

(51) Int. Cl. H01L 21/762; H01L 27/10

(52) U.S. Cl. 257/501; 438/440; 257/E27.07; 257/E21.556

(57) ABSTRACT

Embodiments relate to the lowered reliability of a device due to deterioration caused by the concentration of an electric field in the top corner of an STI. To solve the reliability problem, the STI top corners have a local oxidation of silicon, the top corners of the STI are rounded, and the STI steps are increased in a semiconductor device fabricated according to embodiments. Embodiments relate to an STI in high and low voltage regions of a semiconductor device which can be fabricated by providing a semiconductor substrate having a shallow trench isolation structure, a high voltage region and a low voltage region. A capping layer is formed over the entire surface of the top of the high voltage region and the low voltage region, including the shallow trench isolation structure. A photoresist pattern is formed over the top of the capping layer to expose the high voltage region, including a portion of the shallow trench isolation structure formed within the high voltage region. The capping layer of the high voltage region is removed by performing an etching process using the photoresist pattern as a mask. An oxidation process is performed on the shallow trench isolation structure top corners of the high voltage region from which the capping layer is removed. An ion implantation is then carried out. The ion implantation may be carried out by implanting boron using a tilt method.

The present application claims priority under 35 U.S.C. 119 to Korean Patent Application No. 10-2007-0090912 (filed on Sep. 7, 2007), which is hereby incorporated by reference in its entirety.

### BACKGROUND

As integrated circuits with various functions co-exist in the same product, and semiconductor circuits become more highly integrated, there is a demand for a high voltage or high power transistors for driving multiple voltages and currents. A thin film transistor-liquid crystal device includes a driving circuit and a control circuit. The control circuit includes 5V logic, and the driving circuit includes a high voltage or high power transistor device operating at greater than 30V.

High voltage or high power transistor devices can be manufactured using an STI (Shallow Trench Isolation, hereinafter, STI) process. In an STI process, the topology of STI corners and the doping profile of a semiconductor substrate (e.g., NMOS) exert a very large effect on the device characteristics. FIG. 1 illustrates a device manufactured through an STI process. As boron gathers in the top corners of an STI where a thin gate oxide film is formed, the solubility of the oxide film increases. Therefore, the doping concentration decreases (S1), and an abnormal sub-threshold leakage may occur in a high voltage or high power transistor device. Further, the concentration of an electric field (e.g., a sharpening phenomenon) may cause deterioration, thereby lowering the device reliability.

### SUMMARY

Embodiments relate to a semiconductor device which solves the reliability problem of HV devices generated in a related STI, and a method for fabricating the same. Embodiments relate to an STI in high and low voltage regions of a semiconductor device which can be fabricated by providing a semiconductor substrate having a shallow trench isolation structure, a high voltage region and a low voltage region. A capping layer is formed over the entire surface of the top of the high voltage region and the low voltage region, including the shallow trench isolation structure. A photoresist pattern is formed over the top of the capping layer to expose the high voltage region, including a portion of the shallow trench isolation structure formed within the high voltage region. The capping layer of the high voltage region is removed by performing an etching process using the photoresist pattern as a mask. An oxidation process is performed on the shallow trench isolation structure top corners of the high voltage region from which the capping layer is removed. An ion implantation is then carried out. The ion implantation may be carried out by implanting boron using a tilt method.

A method for fabricating a semiconductor device including a high voltage region and a low voltage region according to another aspect of embodiments includes: providing a semiconductor substrate having a shallow trench isolation structure, a high voltage region and a low voltage region, forming an capping layer over the entire surface of the top of the high voltage region and the low voltage region, including the shallow trench isolation structure, forming a photoresist pattern over top of the capping layer to expose the high voltage region, including a portion of the shallow trench isolation structure formed within the high voltage region, removing the capping layer of the high voltage region by performing an etching process using the photoresist pattern as a mask, performing an oxidation process on the shallow trench isolation structure top corners of the high voltage region from which the capping layer is removed, and carrying out an ion implantation.

Embodiments relate to the lowered reliability of a device due to deterioration caused by the concentration of an electric field in the top corner of an STI. To solve the reliability problem, the STI top corners have a local oxidation of silicon, the top corners of the STI are rounded, and the STI steps are increased in a semiconductor device fabricated according to embodiments.

### DRAWINGS

FIG. 1 is a view showing a semiconductor device fabricated by a related STI process according to the related art.

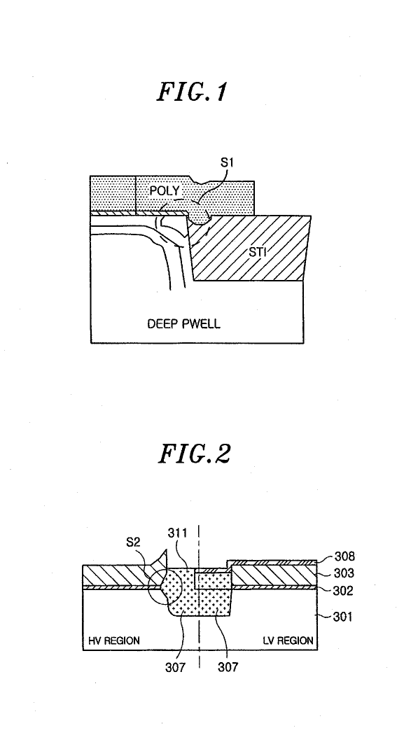

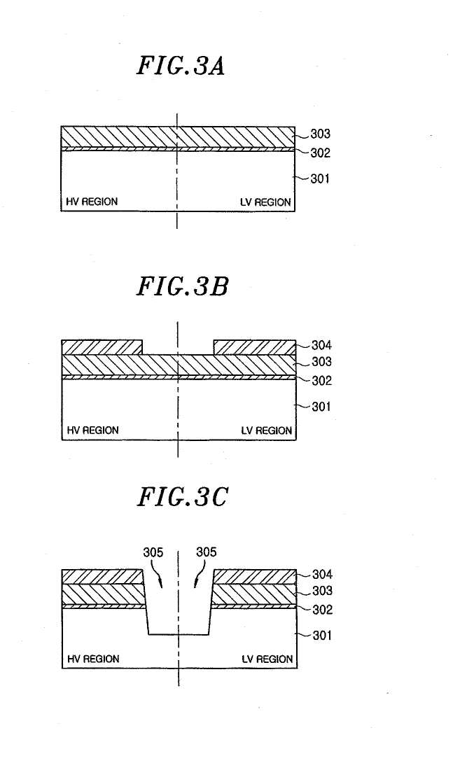

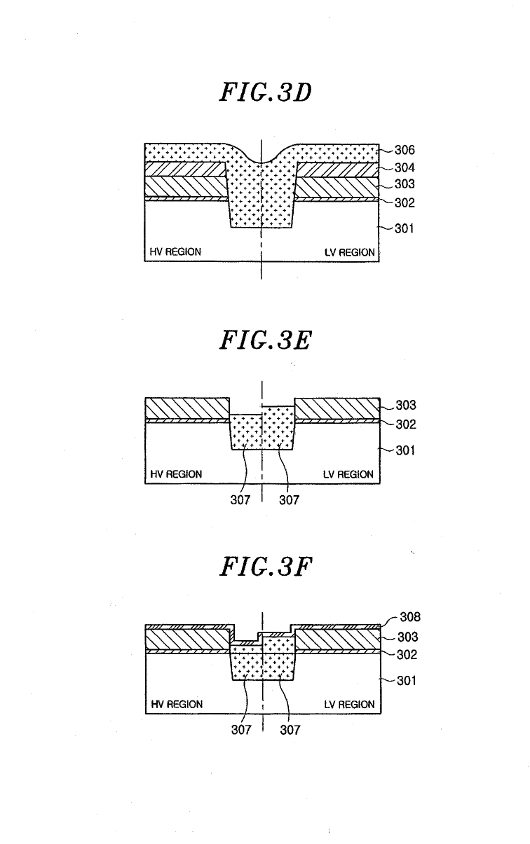

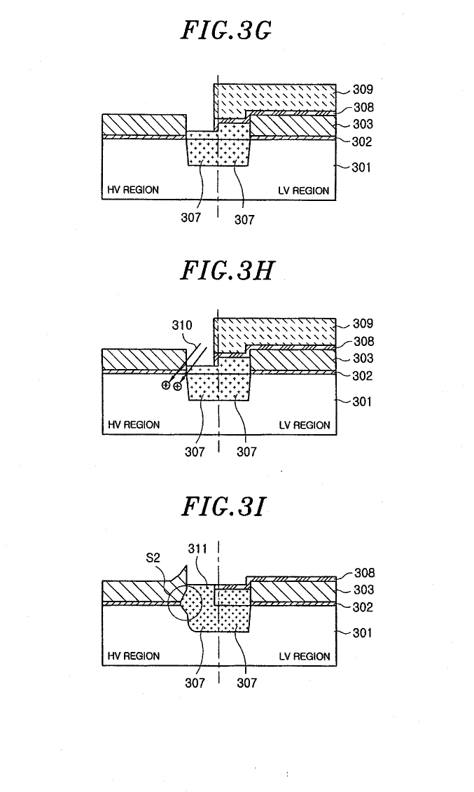

Example FIG. 2 is a vertical cross sectional view of a structure of a semiconductor device fabricated by an STI process in accordance with embodiments.

Example FIGS. 3A to 3I are vertical cross sectional views for each process in a method for fabricating a semiconductor device in accordance with embodiments.

### DESCRIPTION

Example FIG. 2 illustrates a structure of a semiconductor device in which an STI is formed in accordance with embodiments. Referring to example FIG. 2, a pad oxidation film 302 and a nitride film 303 may be sequentially formed over a semiconductor substrate (P-Substrate) 301 which may include a high voltage (hereinafter, HV) region and a low voltage (hereinafter, LV) region. The pad oxidation film 302 and the nitride film 303 may be selectively removed using a PR pattern 304. An STI 305 may be formed using the removed pad oxidation film 302 and nitride film 303 as an etching mask.

An oxide film 306 may be formed thereon and planarized by a planarization process. A capping layer (e.g., a nitride film) 308 may be formed over the entire surface of the planarized top portion. A PR pattern 309 may be formed to open only the HV region, and then the nitride film of the HV region may be removed by a streaming process.

Boron 310 may be deposited in the top corners of the STI (e.g., the STI top edge portions) of the HV region using a tilting ion implantation method. The PR pattern 309 left in the LV region may be removed by a streaming process. An oxidation process 311 may be performed using a dry, high temperature method. Thus, in the overall structure The STI top corner portions have a LOCOS (Local Oxidation of Silicon), the STI top corners are rounded S2, and the STI steps are increased. This new semiconductor device may be used, for example, in high voltage or high power applications.

Example FIGS. 3A to 3I are vertical cross sectional views for each process in a method for fabricating a semiconductor device in accordance with embodiments. Referring to example FIG. 3A, a pad oxidation film 302 and a nitride film 303 are sequentially formed over a semiconductor substrate (P-Substrate, for example, a silicon substrate, a ceramic substrate, a polymer substrate, etc.) 301 including a HV region and an LV region. The pad oxidation film 302 may be formed to a thickness of approximately 200 Å to 300 Å, and the nitride film 303 may be formed to a thickness of approximately 1000 Å to 1500 Å.

Next, part of a photoresist (PR) deposited over the entire surface may be selectively removed by carrying out an exposure and development process using a reticle designed according to a predetermined target pattern. In this way, a PR pattern 304 may be formed over the top of the nitride film 303 to define an STI region as shown in example FIG. 3B.

Afterwards, the pad oxidation film 302 and nitride film 303 may be selectively removed by an etching process using the PR pattern 304 as a mask, to form an STI pattern. The remaining PR pattern 304 may be removed by a streaming process. An etching process (e.g., dry etching) may be performed on the exposed semiconductor substrate 301 to a depth of approximately 1500 Å to 4000 Å using the STI pattern, the pad oxidation film 302 and the nitride film 303 as an etching mask, to thus form an STI 305 as shown in example FIG. 3C.

As shown in example FIG. 3D, an oxide film 306 may be formed over the entire surfaces of the semiconductor substrate 301, pad oxidation film 302, and nitride film 303 including the STI 305. As shown in example FIG. 3E, a CMP (Chemical Mechanical Polishing) planarization process may be performed on the formed oxide film 306, thereby forming a planarized oxide film 307. A stepped portion on the planarized oxide film 307 is generated by the device characteristics in the HV region and the LV region.

As shown in example FIG. 3F, a capping layer (e.g., nitride film) 308 may be formed over the entire surface of the top of the nitride film 303 including the planarized oxide film 307. The nitride film 308 may be formed to a thickness of approximately 100 Å to 500 Å. Next, part of a PR may be deposited over the entire surface. A portion of the PR on HV region may be selectively removed by carrying out an exposure and development process using a reticle designed in an predetermined target pattern to form a PR pattern 304 only in the LV region. This exposes only the HV region. As shown in example FIG. 3G, the nitride film of the HV region is removed by a streaming process.

As shown in example FIG. 3H, boron may be ion-implanted 310 in the top corners of the STI (i.e., STI top edge portions) of the HV region using a tilt method. This ion implant compensates a reduction in doping concentration caused by boron segregation that occurs in the top corner portions of the STI. For example, the ion implantation may be performed at a tilt angle of 20° to 40°, the dose may be approximately 10¹¹ to 10¹², the energy may be approximately 100 to 200 kev, and the doping concentration of the active center and the doping concentration of the STI corners may be the same.

Finally, as shown in example FIG. 3I, boron has been ion-implanted using a tilt method. The PR pattern 309 left in the LV region may be removed by a streaming process. An oxidation process 311 may be performed using a dry method at a high temperature (e.g., within the range of approximately 1000° C. to 1200° C.). While the LV region does not change because the nitride film 308 is capped, the HV region does change. For example, the STI top corner portions have a LOCOS (Local Oxidation of Silicon), the STI top corners S2 are rounded, and the STI steps increase.

Accordingly, in embodiments, the top corners of the STI have a LOCOS, the top corners of the STI are rounded, and the STI steps are increased. This is accomplished, as described above, by forming an STI in a high voltage region and a low voltage region, forming a nitride film as a capping layer over the entire surface of the STI, forming a PR pattern over top of the formed nitride film so as to open only the high voltage region, removing the nitride film of the high voltage region by performing an etching process using the formed PR pattern as a mask, performing an oxidation process on the top corners of the STI of the high voltage region from which the nitride film is removed, and carrying out an ion implantation.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus fabricated by:
providing a semiconductor substrate having a shallow trench isolation structure, a high voltage region and a low voltage region;
forming an capping layer over the entire surface of the top of the high voltage region and the low voltage region, including the shallow trench isolation structure;
forming a photoresist pattern over the capping layer to expose the high voltage region, including a portion of the shallow trench isolation structure formed within the high voltage region;
removing the capping layer of the high voltage region by performing an etching process using the photoresist pattern as a mask;
performing an oxidation process on top corners of the shallow trench isolation structure in the high voltage region from which the capping layer is removed; and
carrying out an ion implantation.

2. The apparatus of claim 1, wherein the capping layer is a nitride film.

3. The apparatus of claim 2, wherein the nitride film is approximately 100 Å to 500 Å thick.

4. The apparatus of claim 1, wherein the ion implantation is carried out by implanting boron using a tilt method.

5. The apparatus of claim 4, wherein the implantation is performed at a tilt angle of 20° to 40°.

6. The apparatus of claim 1, wherein the dose of the ion implantation is 10¹¹ to 10¹², and the energy is 100 to 200 KeV.

7. The apparatus of claim 1, wherein the oxidation process is carried out using a dry method.

8. The apparatus of claim 1, wherein the oxidation process is carried out at a temperature of approximately 1000° C. to 1200° C.

9. A method comprising:
providing a semiconductor substrate having a shallow trench isolation structure, a high voltage region and a low voltage region;
forming an capping layer over the entire surface of the top of the high voltage region and the low voltage region, including the shallow trench isolation structure;
forming a photoresist pattern over the capping layer to expose the high voltage region, including a portion of the shallow trench isolation structure formed within the high voltage region;
removing the capping layer of the high voltage region by performing an etching process using the photoresist pattern as a mask;
performing an oxidation process on top corners of the shallow trench isolation structure in the high voltage region from which the capping layer is removed; and
carrying out an ion implantation.

10. The method of claim 9, wherein the capping layer is a nitride film.

11. The method of claim 10, wherein the nitride film is formed to a thickness of 100 ↑1 to 500 Å.

12. The method of claim 9, wherein the ion implantation is carried out by implanting boron using a tilt method.

13. The method of claim 12, wherein the implantation is performed at a tilt angle of 20° to 40°.

14. The method of claim 9, wherein the dose of the ion implantation is 10¹¹ to 10¹², and the energy is 100 to 200 KeV.

15. The method of claim 14, wherein the oxidation process is carried out using a dry method.

16. The method of claim 9, wherein the oxidation process is carried out at a temperature of approximately 1000° C. to 1200° C.

17. An apparatus comprising:
a semiconductor substrate having a high voltage region and a low voltage region;
a shallow trench isolation structure bridging the high voltage region and the low voltage region;
a capping layer over a portion of the shallow trench isolation structure in the low voltage region;
a local oxidation of silicon in top corner portions of the shallow trench isolation structure in the high voltage region, wherein said top corner portion includes a boron deposit causing said corner portion to be rounded.

18. The apparatus of claim 17, wherein the capping layer is a nitride film.

19. The apparatus of claim 18, wherein the nitride film is formed at a thickness of 100 to 500 Å.

20. The apparatus of claim 17, wherein the shallow trench isolation structure is formed to a depth of approximately 1500 Å to 4000 Å.
